(19) United States
(12) Patent Application Publication
(10) Pub. No.: US 2024/0036143 A1
(43) Pub. Date: Feb. 1, 2024

(54) DYNAMIC VERTICAL SIGNAL CALIBRATION IN A TEST AND MEASUREMENT INSTRUMENT

(71) Applicant: Tektronix, Inc., Beaverton, OR (US)

(72) Inventors: Shubha B, Bengaluru (IN); Krishna N H Sri, Bengaluru (IN); Sathish Kumar K, Sirsi (IN); Yogesh M. Pai, Bengaluru (IN)

(73) Assignee: Tektronix, Inc., Beaverton, OR (US)

(21) Appl. No.: 18/359,789

(22) Filed: Jul. 26, 2023

(30) Foreign Application Priority Data
Jul. 29, 2022 (IN) 202221043518

(51) Int. Cl. G01R 35/00; G01R 31/26

(52) U.S. Cl. CPC G01R 35/005; G01R 31/2601

(57) ABSTRACT

A system for measuring characteristics of wide bandgap Devices Under Test (DUTs) includes a testing fixture including one or more wide bandgap DUTs, and a measurement instrument having one or more processors configured to apply a stimulus to provoke a response of one or more wide bandgap DUTs, measure the response, graph the response on one or more displays, each display having a vertical scale, and automatically adjusting the vertical scale of the one or more displays until no clipping occurs in the one or more displays. Methods of dynamically configuring a test and measurement instrument based on a particular testing setup are also described.

### CROSS-REFERENCE TO RELATED APPLICATIONS

This disclosure claims priority under 35 U.S.C. § 119 to Indian Provisional Patent Application No. 202221043518, filed Jul. 29, 2022, titled “DYNAMIC VERTICAL SIGNAL CALIBRATION BY CONTROLLING A GENERATOR AND POWER SUPPLY FOR WIDE BAND GAP DEVICES,” the disclosure of which is incorporated herein by reference in its entirety.

### TECHNICAL FIELD

The present disclosure relates to test systems for wide-band gap devices. Particularly, the present disclosure relates to a system and method for dynamic vertical signal calibration by controlling a signal generator and power supplies in a system for testing wide band gap devices.

### BACKGROUND

Semiconductor materials used in power electronics are transitioning from silicon-based devices to Wide Band Gap (WBG) semiconductors, such as silicon carbide (SiC) and gallium nitride (GaN). This change in material is due to the superior performance of WBG semiconductors in terms of size, speed, and electrical power compared to their silicon-based predecessors. These increased performance characteristics are increasing the adoption of WBG semiconductors especially for automotive and industrial applications.

Measuring and validating the switching parameters of metal-oxide-semiconductor field-effect transistor (MOSFET) or insulated-gate bipolar transistor (IGBT) devices is commonly performed using the Double Pulse Test (DPT) method. In this method, two pulses are applied on the gate of the device at separate times in an inductive clamp circuit. Fully validating SiC and GaN based WBG uses both static and dynamic measurements. Preferably, this testing is performed early in the design cycle and so can help reduce time to market.

The combination of higher operating frequencies and higher power used in WBG devices reduces measurement reliability. It is often hard to distinguish whether the measured response is a characteristic of the device or a parasitic characteristic of the measurement testing setup, for instance. Plus, existing test solutions use manual methods to control remote testing instruments, which are time consuming and error prone. More specifically, in conventional WBG testing, a user manually adjusts the measurement scales of an instrument until a desired testing range is visible on the output display. Oftentimes this testing is performed by running proprietary scripts on the measurement device and may include managing multiple tests across several different devices. Another problem is that, due to the nature of WBG devices, the pre-tests performed to set up the instruments may cause the WBG devices to perform differently than they would during the actual tests. Thus, in some cases it is impossible to manually set up a testing instrument without realizing long delays, which is commercially unacceptable. Also, in other cases, in which the WBG devices are being tested inside of an elevated temperature chamber, manual adjustment is presently not possible.

Embodiments according to this disclosure address these issues with conventional testing systems.

### BRIEF DESCRIPTION OF THE DRAWINGS

FIG. 1 shows a double pulse testing platform and circuit for WBG devices having an instrument that performs dynamic vertical signal calibration according to embodiments of the disclosure.

FIG. 2 is an example setup screen of an instrument that performs dynamic vertical signal calibration according to embodiments of the disclosure.

FIG. 3A illustrates example setup screens for external and internal signal generators that are controlled by an instrument that performs dynamic vertical signal calibration according to embodiments of the disclosure.

FIG. 3B illustrates example setup screens for low voltage and high voltage power supplies that are controlled by an instrument that performs dynamic vertical signal calibration according to embodiments of the disclosure.

FIG. 3C illustrates example setup screens for manual and automatic instrument calibration for an instrument that performs dynamic vertical signal calibration according to embodiments of the disclosure.

FIG. 4 is a flowchart illustrating example operations to perform dynamic vertical signal calibration according to embodiments of the disclosure.

FIG. 5 is an example screen illustrating typical voltage overshoot experienced by a DUT during an initial testing cycle, according to embodiments of the disclosure.

FIG. 6 is an output display of a measurement instrument illustrating channel clipping caused by the voltage overshoot of FIG. 5, according to embodiments of the disclosure.

FIG. 7 is an output display of a measurement instrument having dynamically adjust vertical displays after three calibration iterations, according to an exemplary implementation of the disclosure.

FIG. 8 is a functional block diagram illustrating an environment within which embodiments of the disclosure operate.

It should be appreciated by those skilled in the art that any block diagrams herein represent conceptual views of illustrative methods embodying the principles of the present disclosure. Similarly, it will be appreciated that any flow charts, flow diagrams, and the like represent various processes which may be substantially represented in computer readable medium and so executed by a computer or processor, whether or not such computer or processor is explicitly shown.

### DETAILED DESCRIPTION

The various embodiments of the present disclosure describe dynamic vertical signal calibration by controlling a generator, power supply, and a test instrument, for wide band gap devices. It further provides an improved system and methods for use in an industrial automation environment.

In the following description, for the purpose of explanation, specific details are set forth in order to provide an understanding of the present disclosure. It will be apparent, however, to one skilled in the art that the present disclosure may be practiced without these details. One skilled in the art will recognize that embodiments of the present disclosure, some of which are described below, may be incorporated into a number of systems.

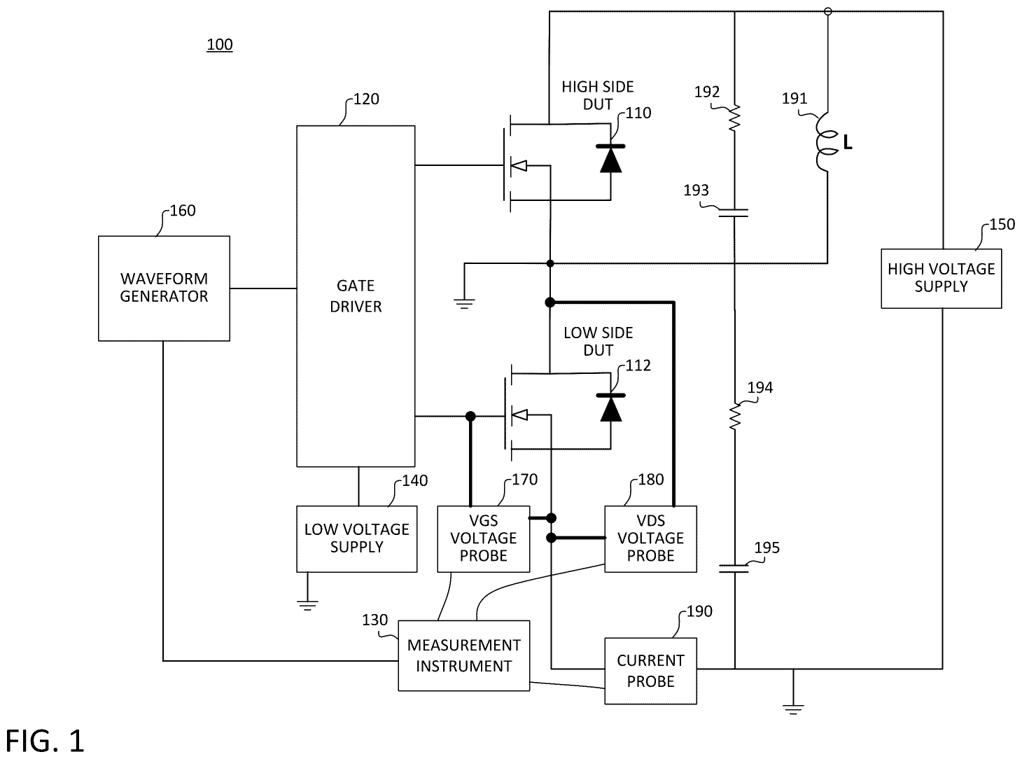

FIG. 1 illustrates a double-pulse testing platform 100 for WBG materials according to embodiments of the disclosure. Generally, two devices, such as a high-side DUT (Device Under Test) 110 and a low-side DUT 112 are the devices tested and may be removably inserted into a physical test fixture (not illustrated) for testing. The DUTs 110, 112 may be MOSFETs or IGBTs formed of SiC, GaN, GaN-HEMT, vertical GaN, and GaN-cascode, for example. The DUTs 110, 112 are controlled by a gate driver 120, which presents voltages to gates of the DUTs 110, 112 for controlling operation of the DUTs. For purposes of this disclosure, reference will be made to DUTs 110, 112 being MOSFET devices, which include a source, a gate and a drain. Embodiments also test IGBTs as the DUTs 110, 112, but use different control voltages, as is known in the art.

A test and measurement instrument 130 is central to the testing platform 100. According to this disclosure, the instrument 130 not only measures parameters of the DUTs 110, 112 being tested and shows the results on a display or saves them to a file for later retrieval, but also controls various components of the testing platform, depending on the particular tests being performed. For instance, according to the disclosure, the instrument 130 controls a low voltage supply 140, high voltage supply 150, and a waveform generator 160 that generates testing signals and sends them to the gate driver 120 for driving the DUTs 110, 112. During an automatic setup process, the instrument 130 also uses results of preliminary responses from the DUTs 110, 112 to control testing parameters of the instrument itself, such as a vertical scale of measurements used during later testing and characterization of the DUTs.

Various probes are used for testing the DUTs 110, 112. A VGS probe 170 measures a gate-to-source voltage, while a VDS probe 180 measures a drain-to-source voltage. As described above, when the DUTs 110, 112 are not MOSFET devices, these probes 170, 180 measure other voltages used to characterize other devices, such as IGBTs. Similarly, a current probe 190 measures current flowing through one or both of the DUTs 110, 120. Other probes may be coupled in other places in the testing platform 100 to measure parameters of the DUTs 110, 112, which are not illustrated here. These other probes may be connected to the instrument 130 through additional measurement channels. By driving the gate driver 120 in certain modes, the testing platform 110 may characterize each of the high side DUT 110 and the low side DUT 112 without the necessity of physically changing the probes 170, 180, and 190, as well as any other probes that may be connected.

In general, during operation, the measurement instrument 130 not only controls the operation of the low side and high side voltage supplies 140, 150, but also controls the waveform generator 160, which in turn drives the gate driver 120 to cause the DUTs 110, 112 to cycle through various modes of the DUTs 110, 112, the results of which are monitored by the probes 170, 180, and 190. During all of this time the measurement instrument 130 is capturing the output of the probes, which is used to characterize the DUTs.

As mentioned above, to provide the most effective measurements, the measurement instrument 130 must be calibrated to the particular DUTs 110, 112 as well as the other components of the testing platform 100. Some of the components that affect testing are parasitic elements of the testing platform, while others are specifically placed on the testing platform to help characterize the DUTs 110, 112. As seen in FIG. 1, some components that may be present in a DPT testing platform 100 may include an inductor 191, a high-side resistor 192, a high-side capacitor 193, a low-side resistor 194, and a low-side capacitor 195. As these components are well known in DPT testing setups, further discussion of them is omitted. But, also as is well known, there may be parasitic elements in the testing platform 100, and the performance of the DUTs 110, 112 may be highly affected by the particular layout and components of a particular testing platform 100. For these reasons, as addressed above, it is impossible to quickly set up the measurement instrument 130 for testing the DUTs 110, 112. For example, to perform accurate measurements, the voltage and current scales of measurement instrument 130 should match those values expected from the DUTs 110, 112 during testing. But, because the variations in the parasitic elements of the testing platform 100, which typically include physical printed circuit boards having large variability, it is impossible for the user to pre-set the voltage and current scales for accurate testing before the testing begins. Embodiments according to the disclosure, as discussed below, automatically characterize the testing platform 100 and adjust the voltage and current scales of the measurement instrument 130 more quickly and accurately than the manual setup used in present testing systems.

More specifically, embodiments according to the disclosure automatically determine the vertical voltage scale (for the measured VGS and VDS voltages) as well as the vertical current scale (for the measured ID current), and then configure the measurement instrument 130 to show measurements of the DUTs 110, 112 using the determined scales. This automatic determination and configuration is optional, and users may instead choose to make such adjustments manually.

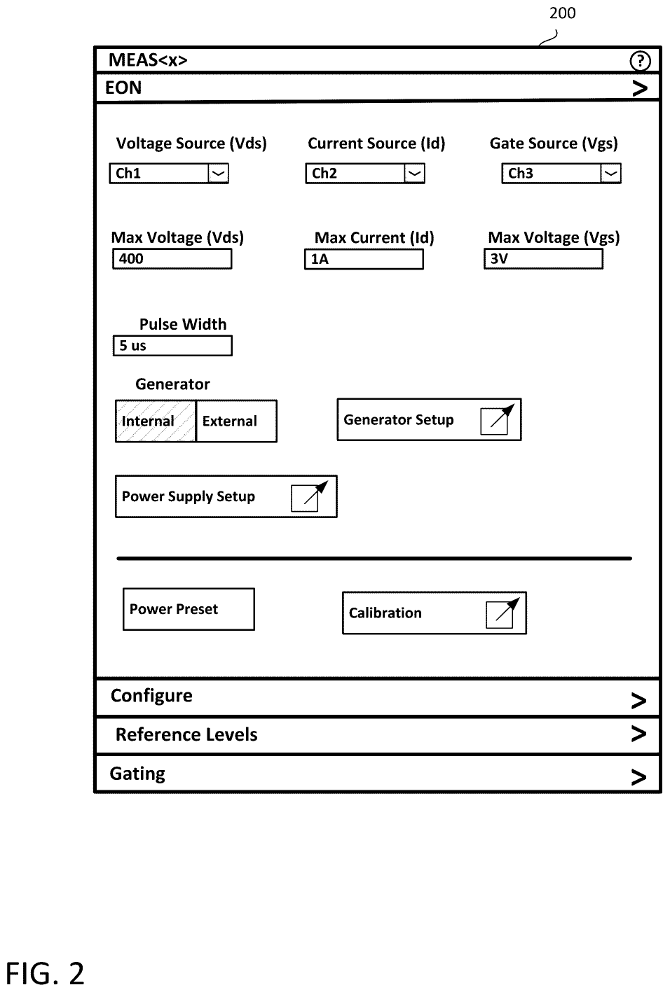

FIG. 2 illustrates an example setup screen 200 through which a user can configure a measurement instrument to perform dynamic signal calibration, according to embodiments of the disclosure. As first steps, the user indicates channel sources to indicate where the VDS voltage probe 180, the VGS voltage probe 170, and the Id current probes 190 are connected to the measurement instrument 130 (FIG. 1). Then, the user may specify maximum voltages and currents expected during the testing, and sets a pulse width that the waveform generator 160 will use to generate gate driving signals for the gate driver 120. Finally, the user specifies whether the generator is external or internal to the instrument.

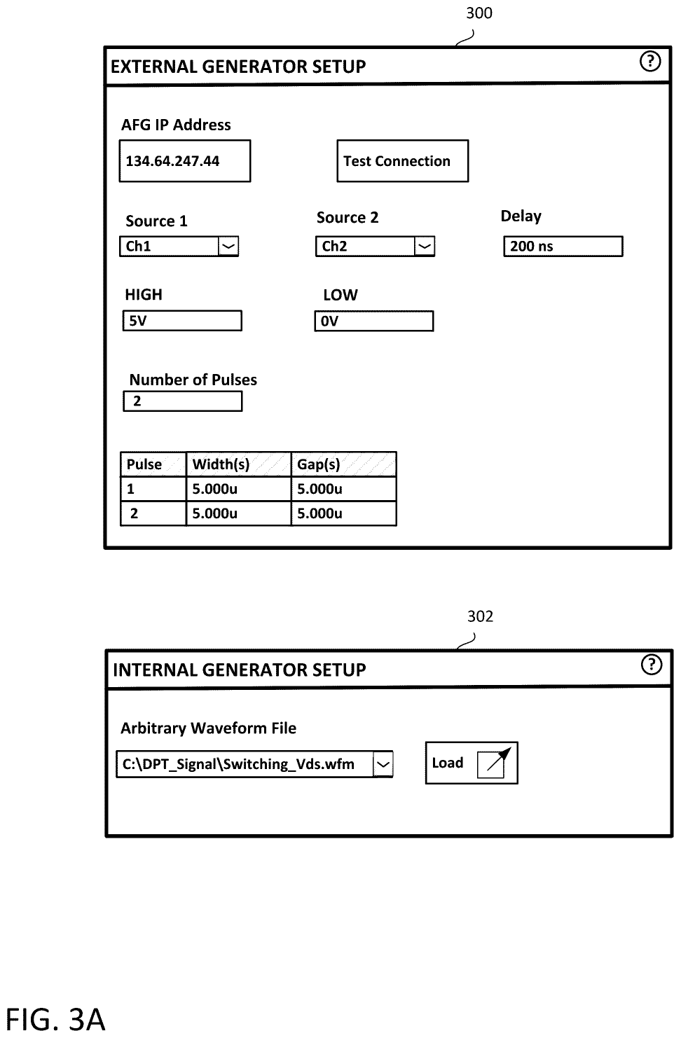

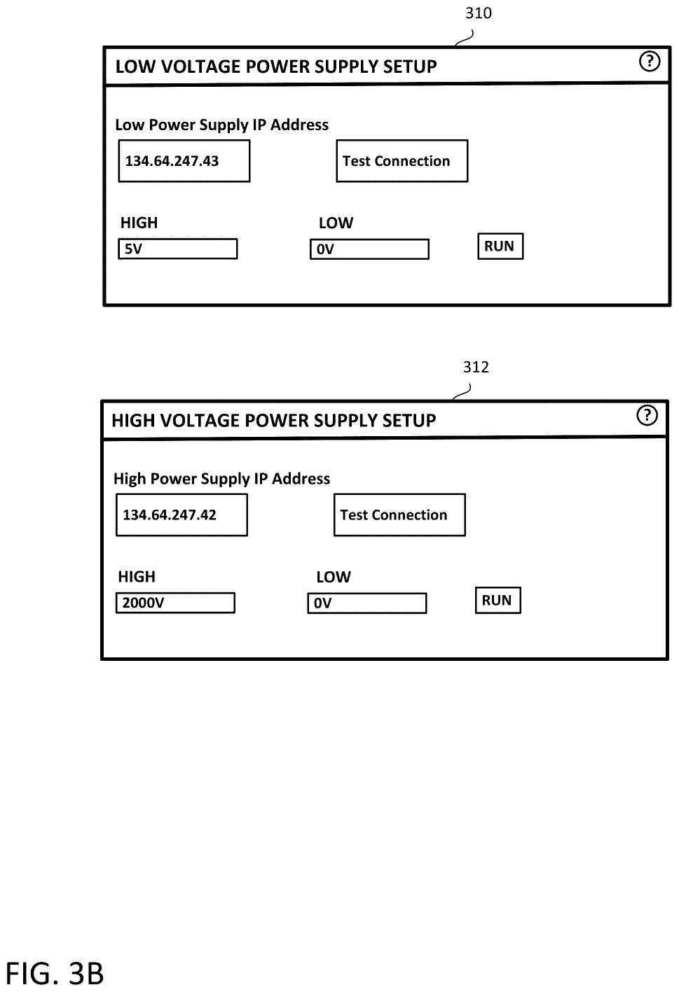

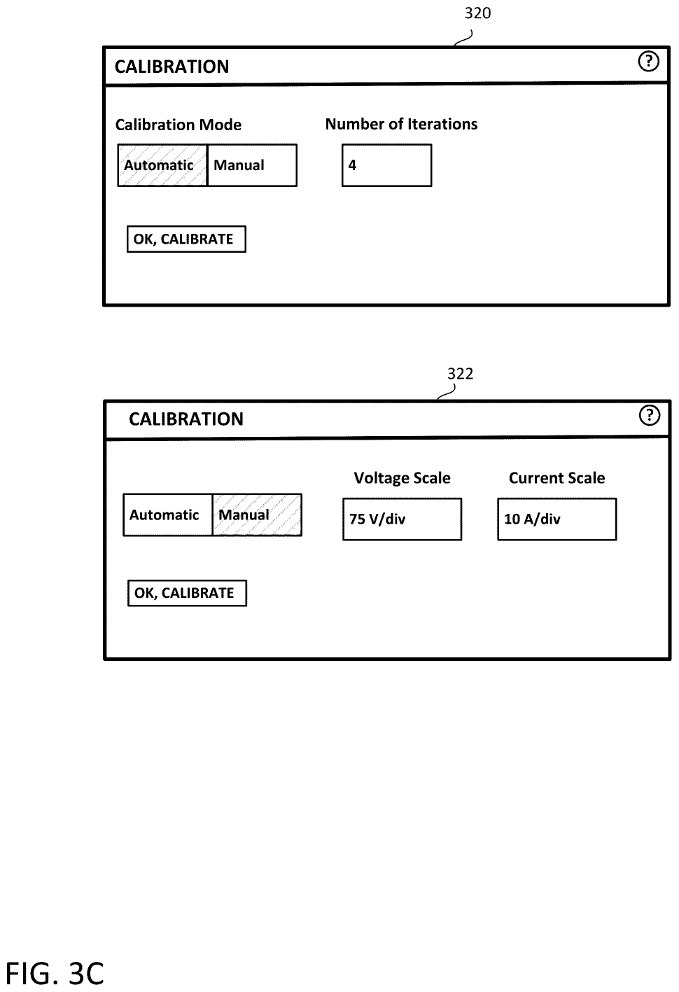

Next, there are setup screens for setting up the generator, setting up either an internal or external waveform generator, setting up the power supplies and setting up the calibration, as illustrated in FIGS. 3A, 3B, and 3C, respectively.

FIG. 3A illustrates an external generator setup sub-screen 300 and an internal generator setup screen 302, either of which appears once the user selects the proper generator setup button from the setup screen 200 of FIG. 2. The external generator setup sub-screen 300 is for specifying parameter for the attached waveform generator 160, which may be an Arbitrary Waveform Generator (AWG), for example. In the generator setup sub screen 300, the user may specify in IP (Internet Protocol) address for the waveform generator. The user may test the connection to the waveform generator 160 by pressing the “test connection” radio button. Further, as illustrated in FIG. 3A, the user may specify other key parameters for the waveform generator 160 such as number of pulses, pulse width of each pulse, gap between each pulse, duty cycle of the pulses, and a delay (dead time) between two channels. The delay time is used when testing the high and low side DUTs 110, 112 simultaneously. If instead an internal generator is being used, the generator setup screen 302 may be used to upload one or more particular files to be used by the internal generator to generate the desired waveforms.

A next step is to set up one or both power supplies. Power supply setup screens 310, 312 are illustrated in FIG. 3B for the low voltage power supply and high voltage power supply, respectively. In each case the user specifies an IP address of the particular power supply, as well as HIGH and LOW voltage limits to be generated by the power supplies. The low voltage power supply 140 (FIG. 1) supplies the power to turn ON isolated gate drive circuits in the gate driver 120, while the high voltage power supply 150 drives the large inductive loads used to test the DUTs 110, 112.

Next the user sets up the calibration parameters, for either automatic calibration, illustrated as setup sub-screen 320 of FIG. 3C, or for manual calibration, illustrated as setup sub-screen 322. In automatic mode, illustrated in sub-screen 320, the user selects the maximum number of iterations in which the instrument performs the dynamic vertical signal calibration. Once the maximum number of iterations are set, the user may initiate calibration by pressing the “OK, Calibrate” radio button. Alternatively, if a manual calibration is desired, as illustrated in the setup sub-screen 322 of FIG. 3C, the user manually specifies both the voltage and current scales, in terms of levels per measurement division. In this example, the user has specified a voltage scale of 75 Volts per division, and has specified a current scale of 10 Amps per division.

After the parameters for the waveform generator 160, low voltage power supply 140, high voltage power supply 150, and calibration mode have been set by the user in the sub-screens illustrated in FIGS. 3A, 3B, and 3C, the user returns to the setup screen 200 of FIG. 2 to initiate the dynamic vertical signal calibration according to embodiments of the disclosure. As described in more detail below, when the user selects the “power preset” radio button of setup screen 200, the measurement instrument 130 automatically determines the proper vertical signal calibration based on the testing platform 100 and DUTs 110, 112 of FIG. 1, and configures the measurement instrument to display measurements in the determined scale. Then the measurement instrument 130 waits in a testing mode to acquire signals from the Double Pulse Testing. Further, when instructed to do so, the measurement instrument drives the waveform generator 160 as well as the low voltage power supply 140 and high voltage power supply 150 according to a pre-programmed sequence to perform the testing itself, without the necessity of further user input.

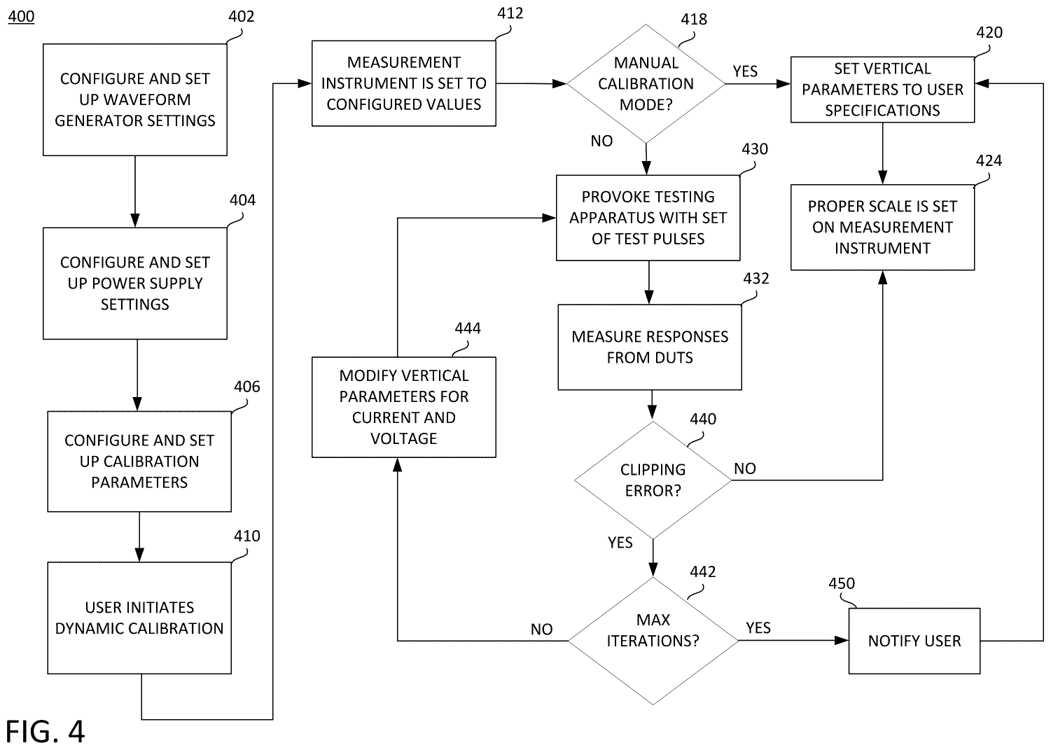

In general, the instrument performs the dynamic vertical signal calibration in a process illustrated in FIG. 4, which is a flowchart showing example operations performed by embodiments according to the disclosure. A flow 400 starts by the user configuring waveform generator settings, power supply settings, and calibration parameters in operations 402, 404, and 406, as respectively described above with reference to FIGS. 2, 3A, 3B, and 3C.

Next, the user initiates the dynamic calibration in an operation 410, such as by pressing the “power preset” radio button in the setup screen 200 of FIG. 2, at which point the measurement instrument 130 is set to the values configured in the preceding steps. A decision block 418 determines if the manual calibration mode was selected by the user in the setup screen 322 of FIG. 3C. If so, the flow 400 exits in the YES direction and the vertical scale parameters are set in the measurement instrument 130 according to the details entered by the user in an operation 420, and the measurement instrument is properly set up in an operation 424.

If instead the user selected to perform dynamic calibration by indicating such in the setup screen 320 of FIG. 3C, then the flow 400 exits the decision block 418 in the NO direction. Next the testing apparatus is stimulated, or provoked, in an operation 430 by a single pulse or set of pulses, as defined by the user in the operations 402, 404, and 406. As part of provoking the testing apparatus, the measurement instrument 130 initiates the waveform generator 160 (FIG. 1), the low voltage supply 140, and the high voltage supply 150. Then the measurement instrument 130 drives the waveform generator 160 to provide pulses to the gate driver 120, which stimulates the DUTs 110, 112. After being provoked in the operation 430, the measurement instrument 130 measures the response or responses from the DUTs 110, 112 from the testing setup 100, in an operation 432.

The first time the DUTs 110, 112 from the testing setup 100 are provoked in the operation 430 of the flow 400, it is very likely that the vertical scale settings of the measurement instrument for either or both of the voltage and current measurements described above will not be set correctly. The reason for this is the influence of the parasitic elements of the testing setup 100, described above with reference to FIG. 1. Further, it is unlikely that the user will be able to accurately predict the initial measurements from the DUTs 110, 112 because of the Double Pulse nature of the testing.

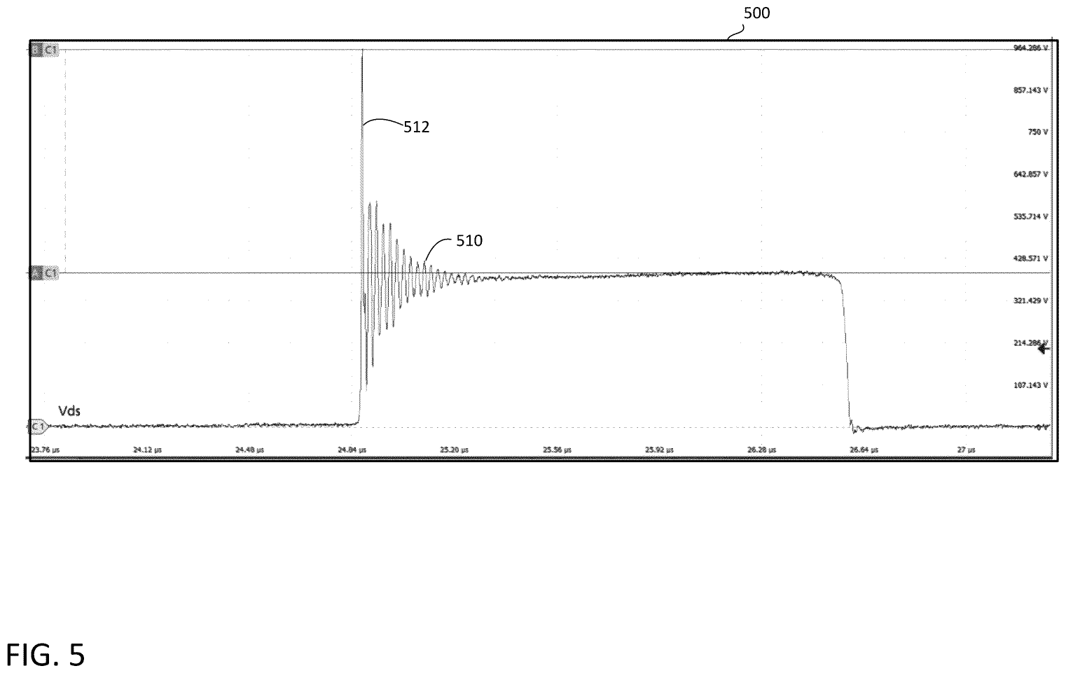

As illustrated in FIG. 5, a voltage signal 510 typically experiences an overshoot 512, or clipping, due to the presence of the parasitic elements of the testing setup 100, as described above. A voltage graph 510 shows a typical overshoot 512 during a turn ON event of one of the DUTs 110, 112. These overshoots occur especially when initial measurements are taken at relatively high temperature of >100 degrees C., and a high voltage>600 Volts, which is a common environment for testing wide band gap materials.

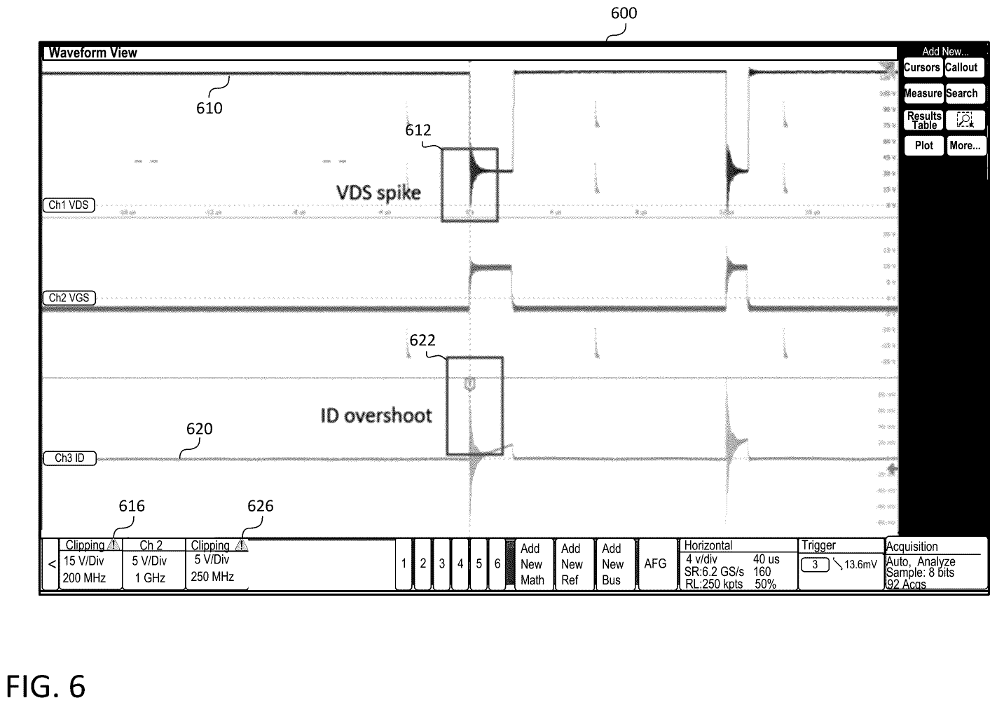

This voltage overshoot illustrated in FIG. 5 results in channel clipping, as illustrated in FIG. 6. FIG. 6 is an output display 600 of measurements of one of the DUTs 110, 112 that is experiencing a voltage overshoot. In FIG. 6, Channel 1 is measuring the VDS voltage from the VDS probe 180 (FIG. 1), Channel 2 is measuring the VGS voltage from the VGS probe 170, and Channel 3 is measuring the ID current from the current probe 190. The VDS voltage is shown as a trace 610, which exhibits a VDS spike 612. Consequent to the voltage spike 612, the ID current, which is shown as a trace 620, also shows an overspike 622, which occurs at the same time as the VDS spike 612. Both of these overspikes 612, 622 are shown on the output display 600 as clipping warnings on Channels 1 and 3, which are labeled as 616 and 626, respectively.

Due to this typical overshoot the first time the DUTs 110, 112 are sampled, the flow 400 inspects the measurements made in the operation 432 in a decision block 440. If, as illustrated above, there is a clipping error in the measurement instrument 130, as illustrated in FIG. 6, the flow 400 exits the decision block 440 in the YES direction, where the flow 400 determines whether the maximum number of iterations entered by the user (FIG. 3C) has been exceeded. If NO, then the flow 400 exits to an operation 444, where the vertical scale of any channel that experienced clipping in the operation 440 is adjusted. In one embodiment, a peak voltage of the measured voltage response is determined and divided into six or more measurement divisions, and the measurement instrument is automatically set to the newly determined scale. The same occurs for current measurements if there was a clipping violation on the channel measuring current.

Then the flow 400 repeatedly performs the operations of provoking the test apparatus in the operation 430, measuring the responses in the operation 432, and checking for clipping in the operation 440.

Once the instrument is configured correctly, that is, the measured response from the DUTs 110, 112 in the operation 432 determines that no clipping has occurred, this means that the vertical scale for the measurement operations has been set correctly, and the flow 400 exits to the operation 424 described above, where the measurement instrument 130 is set correctly. Then the measurement instrument 130 waits in a testing mode to acquire signals from the standard Double Pulse Testing.

In general, embodiments according to the disclosure dynamically set the vertical scale for the measurements in a minimum number of iterations, such as two. It is important that the scales be set with minimal steps because the act of testing the DUTs 110, 112 causes the DUTs and other components in the testing setup 100 to heat up, and this increased temperature can cause inaccurate measurements during the setup process. Also, because there are a relatively large number of devices in the testing setup 100, going through dynamic characterization of all 10-20 switches may impact the speed of testing.

Returning back to the flow 400, if in operation 442 it is determined that the maximum number of iterations entered by the user (FIG. 3C) has been exceeded, then the flow 400 exits to an operation 450, where the user is notified that manual settings should be used.

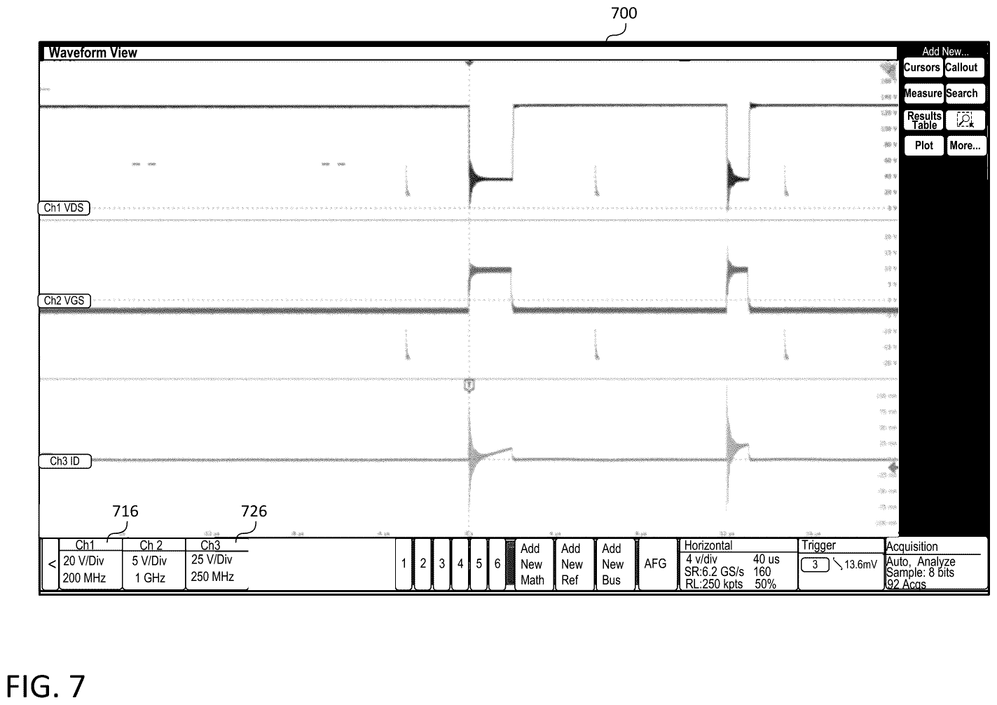

FIG. 7 is an example display 700 with a properly set up measurement instrument for measuring the testing setup 100 where the vertical scales for all measured signals are within the proper measurement range. Notice that unlike in FIG. 6, there are no warning indicators for channel indicators 716 and 726.

Embodiments according to the disclosure address the challenge of quickly and accurately setting up a measurement device for proper measurement of wide bandgap materials in a DPT testing setup, where parasitic elements of the testing setup typically result in large VDS voltage overshoots. The drain to source voltage (VDS) of the DUTs is typically measured on the low side. Wide Band Gap applications operate at higher VDS in the range of 100V to ≥2000V, while drain current (ID) can exceed 100 A, and having temperatures in the range of 15 deg C. to 200 deg C. Embodiments according to the disclosure ensure the scaling is adjusted while accounting the device parasitic.

As described above, because the overshoot spikes vary based on the parasitic of the testing setup and are not easily predictable, embodiments according to the disclosure dynamically and accurately set the measurement scales for the testing setup automatically.

In one example embodiment, using embodiments according to the disclosure, running a single measurement like VDS set to 400V, ID to 10 A at 25 degrees C. takes approximately less than a few seconds, whereas the conventional method, being a manual process, takes a few minutes. This time savings is accumulative, since there are typically hundreds of similar runs in the complete device validation procedure.

Embodiments according to the disclosure allow the user to fully automate the test system and gives the user the flexibility to control the instruments using Python, MATLAB or LabVIEW scripts through a programmatic interface of the measurement instrument.

Further, using embodiments according to the disclosure, users have the flexibility to choose between an internal or an external waveform generator. Embodiments allow users to recall pre-saved double pulse waveforms, such as illustrated in FIG. 3A.

Still further, embodiments according to the disclosure provide an ability to test high side and low side DUTs 110, 112 simultaneously with a specified dead time, i.e., delay, by controlling the respective gate drivers, as shown in the setup screen 300 of FIG. 3A.

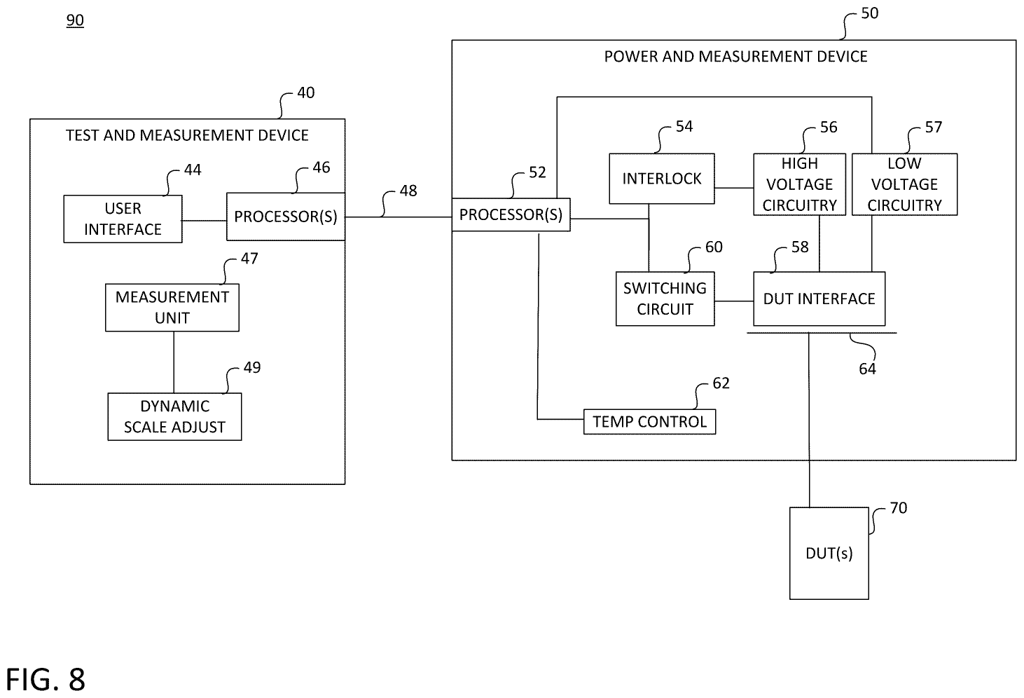

FIG. 8 is a block diagram illustrating a test and measurement system 90, which may also be referred to as a testing platform, including dynamic signal calibration according to embodiments of the disclosure. The test and measurement system 90 includes a test and measurement device 40, such as an oscilloscope or other test and measurement device. For ease of discussion, the device 40 may be referred to as a measurement device. Another other part of the system 90 is a power and measurement device 50, which will be referred to as a power device for ease of discussion. These terms are not intended to limit the capabilities of either device, so no such limitation should be implied.

The measurement device 40 may have many different components, including a user interface 44 that allows a user to interact with various menus on the measurement device. The user interface 44 allows the user to make selections as to the tests to be run, set parameters, etc., such as through a display having a touch screen or various buttons and knobs. The measurement device 40 has one or more processors 46 that receive the user inputs and send the parameters and other selections to the measurement device and may receive output from the power device and generate outputs for the user from the data. The measurement device 40 includes a measurement unit 47 that performs tests and measures parameters of the DUT. Further, the measurement device 40 includes a dynamic scale adjuster 49, which operates in conjunction with the measurement unit 47 in the manner described above with reference to flow 400 of FIG. 4.

The term “processor” as used here means any electronic component or components that can receive an instruction and perform an action, such as one or more microcontrollers, field programmable gate arrays (FPGA), and/or application-specific integrated circuits (ASIC), as will be discussed in more detail further.

The measurement device 40 communicates with the power device 50 through a cable or other direct connection 48. This connection 48 may be a network cable, such as a LAN cable. The cable 48 connects to each device through connection circuitry that allows the devices to switch configurations without having to re-cable.

The power device 50 may also have several different elements. These may include one or more processors 52, high voltage circuitry 56 that provides high voltage to the device under test (DUT), and an interlock 54 that acts as a protection for the high voltage circuitry. The interlock is designed to prevent device damage or any dangerous conditions resulting from the high voltage produced by the high voltage circuitry. Low voltage circuitry 57 provides low voltages for circuit operation as described above. A DUT interface 58 couples to an externally mounted DUT 70. The DUT 70 may actually include more than one separate device, as described above, depending on the testing configuration. The DUT interface 58 may be embodied by a universal DUT interface that allows the DUT 70 to connect to the various components in the power device 50. The power device 50 may also include a barrier 64 to protect the device 50 from the DUT 70.

High voltage circuitry within the power device 50 as well as the operation of the DUTs 70 may generate heat, and/or the DUTs may need a particular temperature range to operate. The power device 50 may include temperature control circuitry 62 to control the temperature of the DUT 70. The one or more processors 52 monitor the temperature and operate the temperature control 62 which may comprise items such as fans, switchable heat sinks, cooling systems, heaters, etc. The power device 50 may also include a switching circuit 60, which controls operation of various components within the power device to test and measure the DUTs 70.

Generally, in operation, a user invokes dynamic vertical signal calibration on the test and measurement device 40, which operates as described above. Specifically, the test and measurement device 40 includes a facility to dynamically adjust the measurement scales of the measurement unit to automatically configure the test and measurement device specifically for wide bandgap testing of the DUTs 70.

Aspects of the disclosure may operate on a particularly created hardware, on firmware, digital signal processors, or on a specially programmed general-purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### Examples

Illustrative examples of the disclosed technologies are provided below. An embodiment of the technologies may include one or more, and any combination of, the examples described below.

Example 1 is a system for measuring characteristics of wide bandgap Devices Under Test (DUTs), including a testing fixture including one or more wide bandgap DUTs and a measurement instrument having one or more processors configured to apply a stimulus that provokes a response of one or more wide bandgap DUTs, measure the response, graph the response on one or more displays, each display having a vertical scale, and automatically adjust the vertical scale of the one or more displays until no clipping occurs in the one or more displays.

Example 2 is a system according to Example 1, in which applying the stimulus comprises using the measurement instrument to drive a waveform generator of the testing fixture.

Example 3 is a system according to Example 2, in which the waveform generator produces at least two signals, and includes a pre-selected delay between the at least two signals.

Example 4 is a system according to any of the preceding Examples, further comprising using the measurement instrument to control a low side power voltage supply and a high side power voltage supply of the testing fixture.

Example 5 is a system according to any of the preceding Examples, in which measuring a response comprises measuring a drain-to-source voltage of the one or more wide bandgap DUTs, a gate-to-source voltage of the one or more wide bandgap DUTs, or a drain current of the one or more wide bandgap DUTs.

Example 6 is a system according to any of the preceding Examples, in which automatically adjusting the vertical scale of the one or more displays is performed iteratively.

Example 7 is a system according to Example 6, in which iteratively adjusting the vertical scale includes repeatedly adjusting the vertical scale of the one or more displays, measuring the response using the adjusted vertical scale, and evaluating the one or more displays to determine if clipping occurred on the one or more displays, until no more clipping occurs on the one or more displays.

Example 8 is a system according to Example 6, in which iteratively adjusting the vertical scale includes repeatedly adjusting the vertical scale of the one or more displays, measuring the response using the adjusted vertical scale, and evaluating the one or more displays to determine if clipping occurred on the one or more displays, until a maximum number of iterations has occurred

Example 9 is a system according to any of the preceding Examples, in which the testing fixture includes a temperature control for setting a temperature of one or more wide bandgap DUTs, and in which the measurement instrument is configured to operate the temperature control.

Example 10 is a method for automatically setting a vertical scale of a measurement display in a test and measurement instrument coupled to a testing fixture including one or more wide bandgap DUTs, the method including applying a stimulus to provoke a response of one or more wide bandgap DUTs, measuring the response, graphing the response on one or more displays, each display having a vertical scale, and automatically adjusting the vertical scale of the one or more displays until no clipping occurs in the one or more displays.

Example 11 is a method according to Example 10, in which applying a stimulus comprises driving a waveform generator of the testing fixture by the measurement instrument.

Example 12 is a method according to Example 11, in which driving the waveform generator comprises producing at least two signals separated by a pre-selected delay time.

Example 13 is a method according to any of the preceding Example methods, further comprising controlling a low side voltage power supply and a high side voltage power supply of the testing fixture by the measurement instrument.

Example 14 is a method according to any of the preceding Example methods, in which measuring a response comprises measuring a drain-to-source voltage of the one or more wide bandgap DUTs, a gate-to-source voltage of the one or more wide bandgap DUTs, or a drain current of the one or more wide bandgap DUTs.

Example 15 is a method according to any of the preceding Example methods, in which automatically adjusting the vertical scale of the one or more displays is performed iteratively.

Example 16 is a method according to Example 15, in which iteratively adjusting the vertical scale includes repeatedly adjusting the vertical scale of the one or more displays, measuring the response using the adjusted vertical scale, and evaluating the one or more displays to determine if clipping occurred on the one or more displays, until no more clipping occurs on the one or more displays.

Example 17 is a method according to Example 15, in which iteratively adjusting the vertical scale includes repeatedly adjusting the vertical scale of the one or more displays, measuring the response using the adjusted vertical scale, and evaluating the one or more displays to determine if clipping occurred on the one or more displays, until a maximum number of iterations has occurred.

Example 18 is a method according to any of the preceding Example methods, in which the testing fixture includes a temperature control for setting a temperature of one or more wide bandgap DUTs, the method further comprising operating the temperature control by the measurement instrument.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific examples of the invention have been illustrated and described for purposes of illustration, it will be understood that various modifications may be made without departing from the spirit and scope of the invention. Accordingly, the invention should not be limited except as by the appended claims.

We claim:

1. A system for measuring characteristics of wide bandgap Devices Under Test (DUTs), comprising:
a testing fixture including one or more wide bandgap DUTs; and
a measurement instrument having one or more processors configured to:
apply a stimulus that provokes a response of one or more wide bandgap DUTs,
measure the response,
graph the response on one or more displays, each display having a vertical scale, and
automatically adjust the vertical scale of the one or more displays until no clipping occurs in the one or more displays.

2. The system according to claim 1, in which applying the stimulus comprises using the measurement instrument to drive a waveform generator of the testing fixture.

3. The system according to claim 2, in which the waveform generator produces at least two signals, and includes a pre-selected delay between the at least two signals.

4. The system according to claim 1, further comprising using the measurement instrument to control a low side power voltage supply and a high side power voltage supply of the testing fixture.

5. The system according to claim 1, in which measuring a response comprises measuring a drain-to-source voltage of the one or more wide bandgap DUTs, a gate-to-source voltage of the one or more wide bandgap DUTs, or a drain current of the one or more wide bandgap DUTs.

6. The system according to claim 1, in which automatically adjusting the vertical scale of the one or more displays is performed iteratively.

7. The system according to claim 6, in which iteratively adjusting the vertical scale includes repeatedly:
adjusting the vertical scale of the one or more displays,
measuring the response using the adjusted vertical scale, and
evaluating the one or more displays to determine if clipping occurred on the one or more displays, until no more clipping occurs on the one or more displays.

8. The system according to claim 6, in which iteratively adjusting the vertical scale includes repeatedly:
adjusting the vertical scale of the one or more displays,
measuring the response using the adjusted vertical scale, and
evaluating the one or more displays to determine if clipping occurred on the one or more displays, until a maximum number of iterations has occurred.

9. The system according to claim 1, in which the testing fixture includes a temperature control for setting a temperature of one or more wide bandgap DUTs, and in which the measurement instrument is configured to operate the temperature control.

10. A method for automatically setting a vertical scale of a measurement display in a test and measurement instrument coupled to a testing fixture including one or more wide bandgap DUTs, the method comprising:
applying a stimulus to provoke a response of one or more wide bandgap DUTs;
measuring the response;
graphing the response on one or more displays, each display having a vertical scale; and
automatically adjusting the vertical scale of the one or more displays until no clipping occurs in the one or more displays.

11. The method according to claim 10, in which applying a stimulus comprises driving a waveform generator of the testing fixture by the measurement instrument.

12. The method according to claim 11, in which driving the waveform generator comprises producing at least two signals separated by a pre-selected delay time.

13. The method according to claim 10, further comprising controlling a low side voltage power supply and a high side voltage power supply of the testing fixture by the measurement instrument.

14. The method of claim 10, in which measuring a response comprises measuring a drain-to-source voltage of the one or more wide bandgap DUTs, a gate-to-source voltage of the one or more wide bandgap DUTs, or a drain current of the one or more wide bandgap DUTs.

15. The method of claim 10, in which automatically adjusting the vertical scale of the one or more displays is performed iteratively.

16. The method according to claim 15, in which iteratively adjusting the vertical scale includes repeatedly:
adjusting the vertical scale of the one or more displays,
measuring the response using the adjusted vertical scale, and
evaluating the one or more displays to determine if clipping occurred on the one or more displays, until no more clipping occurs on the one or more displays.

17. The method according to claim 15, in which iteratively adjusting the vertical scale includes repeatedly:
adjusting the vertical scale of the one or more displays,
measuring the response using the adjusted vertical scale, and
evaluating the one or more displays to determine if clipping occurred on the one or more displays, until a maximum number of iterations has occurred.

18. The method according to claim 10, in which the testing fixture includes a temperature control for setting a temperature of one or more wide bandgap DUTs, the method further comprising operating the temperature control by the measurement instrument.
